(19) United States
(12) Patent Application Publication
(10) Pub. No.: US 2009/0108463 A1
(43) Pub. Date: Apr. 30, 2009

(54) METHOD OF MANUFACTURING SEMICONDUCTOR DEVICE AND SEMICONDUCTOR DEVICE

(75) Inventor: Sergey PIDIN, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU MICROELECTRONICS LIMITED, Tokyo (JP)

(21) Appl. No.: 12/251,773

(22) Filed: Oct. 15, 2008

(30) Foreign Application Priority Data
Oct. 24, 2007 (JP) 2007-276629

(51) Int. Cl. H01L 21/768; H01L 23/535

(52) U.S. Cl. 257/774; 438/675; 257/E21.586; 257/E23.168

(57) ABSTRACT

According to an aspect of an embodiment, a method of manufacturing a semiconductor device has forming a wiring layer over a substrate, forming a first film over the wiring layer, forming a second film over the first film, selectively etching the first and second films to form an first end of the first and second films over the wiring layer, forming a third film over the second film, selectively etching the third film to form a second end of the third film tapered off over the first end of the first and second films, forming an interlayer insulating film over the second and third films, forming a contact hole by selectively etching the interlayer insulating film, the first film, the second film and the third film, and forming a contact plug connected to the wiring layer in the contact holes.

### CROSS-REFERENCE TO RELATED APPLICATION

This application is based upon and claims the benefit of priority of the prior Japanese Patent Application No. 2007-276629 filed on Oct. 24, 2007, the entire contents of which are incorporated herein by reference.

### BACKGROUND

1. Field

The embodiments discussed herein are directed to a method of manufacturing a semiconductor device and a semiconductor device.

2. Description of Related Art

In recent years, to improve the carrier mobility of a field-effect transistor, a method of applying a predetermined stress to a channel of the field-effect transistor to impart strain to the crystal of the channel has been reported. Specifically, a tensile stress film is formed on the surface of an n-type field-effect transistor. A compressive stress film is formed on the surface of a p-type field-effect transistor. The tensile stress film and the compressive stress film are laminated at the boundary between the n-type field-effect transistor and the p-type field-effect transistor.

Hitherto, in semiconductor devices including such field-effect transistors, a layout in which a lead formed between an n-type field-effect transistor and a p-type field-effect transistor has been used. In such a layout, a superposed portion of a tensile stress film and a compressive stress film is formed on the lead. Furthermore, the tensile stress film and the compressive stress film are separately formed; hence, an etch stop is formed on one of the stress films.

In a step of separately forming the stress films, the etch stop for one of the stress films is disadvantageously left at an end of the superposed portion of the stress films. When a contact hole for forming a contact plug serving as a lead is formed in the superposed portion described above, the stress film located below the remaining etch stop is not etched, thus causing the occurrence of a faulty opening of the contact hole below the etch stop. Therefore, in the case where the contact hole is filled with a conductive member to form a contact plug, the continuity failure of the resulting contact plug occurs.

To prevent the occurrence of the continuity failure of the contact plug, for example, Japanese Laid-open Patent Publication No. 2007-88452 discloses a technique in which a lead is formed in a region other than a superposed portion of a tensile stress layer and a compressive stress layer, the region being located between an n-type field-effect transistor and a p-type field-effect transistor.

### SUMMARY

According to an aspect of an embodiment, a method of manufacturing a semiconductor device has forming a wiring layer over a substrate, forming a first film over the wiring layer, forming a second film over the first film, selectively etching the first and second films to form an first end of the first and second films over the wiring layer, forming a third film over the second film, selectively etching the third film to form a second end of the third film tapered off over the first end of the first and second films, forming an interlayer insulating film over the second and third films, forming a contact hole by selectively etching the interlayer insulating film and the first film, the second film and the third film, and forming a contact plug connected to the wiring layer in the contact holes.

### BRIEF DESCRIPTION OF THE DRAWINGS

FIG. 1A is a plan view of a semiconductor device according to the present embodiment, and FIG. 1B is a cross-sectional view of the semiconductor device according to the present embodiment;

FIGS. 2A and 2B illustrate a manufacturing process of a semiconductor device according to the present embodiment;

FIGS. 3A and 3B illustrate the manufacturing process of the semiconductor device according to the present embodiment;

FIGS. 4A and 4B illustrate the manufacturing process of the semiconductor device according to the present embodiment;

FIGS. 5A and 5B illustrate the manufacturing process of the semiconductor device according to the present embodiment;

FIGS. 6A and 6B illustrate the manufacturing process of the semiconductor device according to the present embodiment;

FIGS. 7A and 7B illustrate the manufacturing process of the semiconductor device according to the present embodiment;

FIG. 8 illustrates the manufacturing process of the semiconductor device according to the present embodiment; and

FIG. 9 is a table that shows etch rates of an interlayer insulating film and a silicon nitride film constituting a third film.

### DESCRIPTION OF THE PREFERRED EMBODIMENTS

While embodiments of the structure of a semiconductor device and a method of manufacturing a semiconductor device according to an embodiment of the present embodiment will be described below, the present technique is not limited to these embodiments.

In a method of manufacturing a semiconductor device and a semiconductor device according to embodiments, a contact plug is formed in a region having an end of a third film formed on a second film provided on the lead and having a shape such that the thickness of the end of the third film differs from the thickness of another region of the third film, thereby preventing the occurrence of the continuity failure of the contact plug.

Furthermore, a step of forming the region having the end of the third film on the second film and having the shape such that the thickness of the end of the third film differs from the thickness of another region of the third film on the lead results in the prevention of the formation of faulty openings in a step of forming contact holes, thereby preventing the occurrence of the continuity failure of the contact plug.

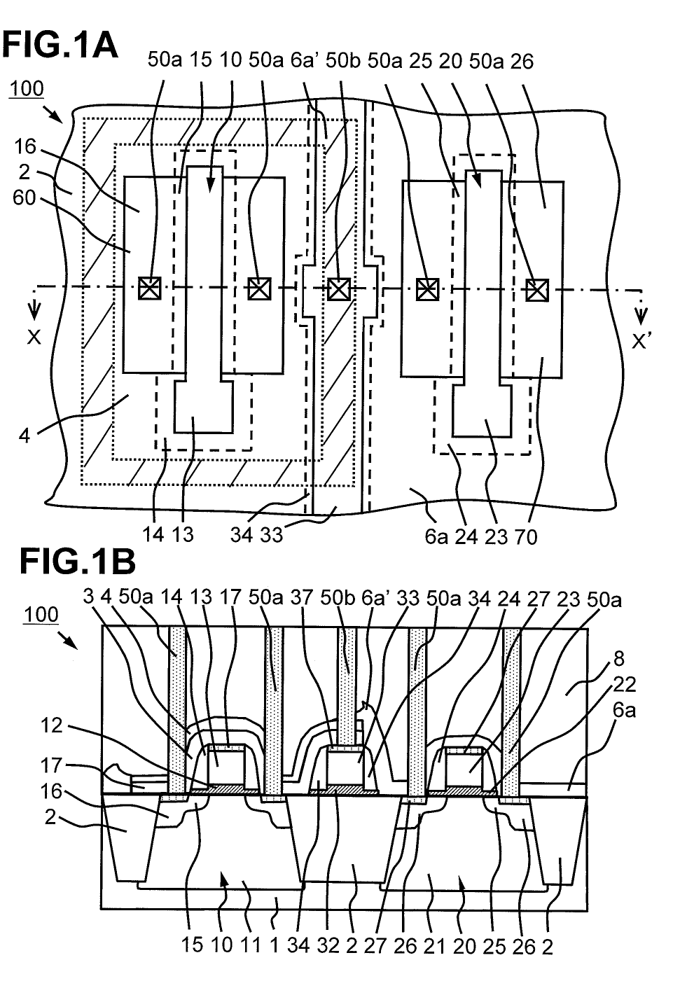

FIGS. 1A and 1B illustrate the structure of a semiconductor device 100 according to an embodiment. FIG. 1A is a plan view of the semiconductor device 100. FIG. 1B is a cross-sectional view of the semiconductor device 100, the view being taken along line X-X′ in FIG. 1A.

FIG. 1A illustrates a second film 4, a third film 6a, a region 6a′ having a shape such that the thickness of the end of the third film differs from the thickness of another region of the third film, an n-type metal insulator semiconductor (MIS) transistor 10, a gate electrode 13, side walls 14, p-type MIS transistor 20, a gate electrode 23, side walls 24, a lead 33, side walls 34, contact plugs 50a and 50b, an active region 60, and an active region 70. The MIS transistor represents a field-effect transistor.

As shown in FIG. 1A, element isolation regions 2 are formed around the n-type MIS transistor 10 and the p-type MIS transistor 20.

The active region 60 of the n-type MIS transistor 10 has a rectangular shape defined by the element isolation regions 2. The gate electrode 13 of the n-type MIS transistor 10 is formed in such a manner that the rectangular pattern of the gate electrode 13 is formed across the center of the active region 60.

The active region 70 of the p-type MIS transistor 20 has a rectangular shape defined by the element isolation regions 2. The gate electrode 23 of the p-type MIS transistor 20 is formed in such a manner that the rectangular pattern of the gate electrode 23 is formed across the center of the active region 70.

The lead 33 is formed between the n-type MIS transistor 10 and the p-type MIS transistor 20. In this embodiment, the lead 33 is formed in parallel with the gate electrode 13 of the n-type MIS transistor 10 and with the gate electrode 23 of the p-type MIS transistor 20. However, the lead 33 need not be formed in parallel with the gate electrode 13 of the n-type MIS transistor 10 or with the gate electrode 23 of the p-type MIS transistor 20 but may be perpendicularly formed.

The side walls 14 are formed around the gate electrode 13 of the n-type MIS transistor 10. The side walls 24 are formed around the gate electrode 23 of the p-type MIS transistor 20. Side walls 34 are formed around the lead 33.

Source/drain extension regions 15 of the n-type MIS transistor 10 are formed in the active region 60, adjacent to the gate electrode 13, and each have a predetermined width. Heavily doped source/drain regions 16 of the n-type MIS transistor 10 are formed in a region of the active region 60 other than the source/drain extension regions 15 and the gate electrode 13.

Source/drain extension regions 25 of the p-type MIS transistor 20 are formed in the active region 70, adjacent to the gate electrode 23, and each have a predetermined width. Heavily doped source/drain regions 26 of the p-type MIS transistor 20 are formed in a region of the active region 70 other than the source/drain extension regions 25 and the gate electrode 23. The gate electrode 13, the source/drain regions 16, the gate electrode 23, the source/drain regions 26, and the lead 33 are referred to as contact electrodes.

The second film 4 is formed in a region where the n-type MIS transistor 10 is formed. The second film 4 has a rectangular shape. The second film 4 is composed of silicon oxide. The second film 4 underlies the region 6a′ having a shape such that the thickness of the end of the third film differs from the thickness of another region of the third film described below.

The third film 6a is formed on the p-type MIS transistor 20 and a region other than a rectangular region including the n-type MIS transistor 10. The third film 6a has the region 6a′ having the shape such that the thickness of the end of the third film differs from the thickness of another region of the third film, the region 6a′ surrounding the rectangular region including the n-type MIS transistor 10. The third film 6a is composed of silicon nitride having a lower etch resistance than that of the material of the second film 4. The region 6a′ having the shape such that the thickness of the end of the third film differs from the thickness of another region of the third film is formed by isotropic etching described below so as to have a tapered shape. Thus, the region 6a′ has a thickness smaller than that of the third film 6a. The region 6a′ having the shape such that the thickness of the end of the third film differs from the thickness of another region of the third film is partially formed in parallel with the lead 33.

The contact plugs 50a are formed in the heavily doped source/drain regions 16 of the n-type MIS transistor 10 and the heavily doped source/drain regions 26 of the p-type MIS transistor 20. The contact plugs 50a formed in a region where the n-type MIS transistor 10 is formed are electrically connected to the heavily doped source/drain regions 16 of the n-type MIS transistor 10. The contact plugs 50a formed in a region where the p-type MIS transistor 20 is formed are electrically connected to the heavily doped source/drain regions 26 of the p-type MIS transistor 20. The contact plugs 50a are formed in regions where the second film 4 and the third film 6a are formed.

The contact plug 50b is formed in a region where the lead 33 is formed. The contact plug 50b is formed between the n-type MIS transistor 10 and the p-type MIS transistor 20. The contact plug 50b is formed in the region 6a′ having the shape such that the thickness of the end of the third film differs from the thickness of another region of the third film described below. The contact plug 50b is electrically connected to the lead 33.

FIG. 1B illustrates a silicon substrate 1, the element isolation regions 2, a first film 3, the silicon oxide film 4, the third film 6a, the region 6a′ having the shape such that the thickness of the end of the third film differs from the thickness of another region of the third film, interlayer insulating film 8, the n-type MIS transistor 10, a p-type well region 11, a gate insulating film 12, the gate electrode 13, the side walls 14, the source/drain extension regions 15, the heavily doped source/drain regions 16, silicide layers 17, the p-type MIS transistor 20, an n-type well region 21, a gate insulating film 22, the side walls 24, the source/drain extension regions 25, the heavily doped source/drain regions 26, silicide layers 27, a gate insulating film 32, the lead 33, side walls 34, a silicide layer 37, the contact plugs 50a, and the contact plug 50b. In FIG. 1B, the same elements described in FIG. 1A are designated using the same reference numerals.

The structure of the n-type MIS transistor 10 will be described below.

The p-type well region 11 is formed by ion implantation with a dopant for imparting p-type conductivity to the silicon substrate 1.

The gate insulating film 12 is formed in the p-type well region 11 of the silicon substrate 1.

The gate electrode 13 is formed on the silicon substrate 1 with the gate insulating film 12 provided therebetween. The gate electrode 13 has a thickness of, for example, about 100 nm. The gate electrode 13 has a width of, for example, about 25 nm to about 90 nm. The gate electrode 13 is preferably composed of polysilicon.

The side walls 14 are formed on side walls of the gate electrode 13. The side walls 14 are preferably composed of silicon oxide, which is an insulating material.

The source/drain extension regions 15 are formed by ion implantation with a dopant for imparting n-type conductivity. The source/drain extension regions 15 are adjacent to long sides of the rectangular pattern of the gate electrode 13, each have a width of, for example, 5 nm to 10 nm, and each have a maximum depth of, for example, 20 nm to 40 nm from the surface of the silicon substrate 1.

The heavily doped source/drain regions 16 are adjacent to ends of the side walls 14 and have a predetermined width. As shown in FIG. 1A, the heavily doped source/drain regions 16 are formed in the active region 60 except the gate electrode 13. The heavily doped source/drain regions 16 preferably have a maximum depth of, for example, 90 nm from the surface of the silicon substrate 1.

The silicide layers 17 are formed on surfaces of the gate electrode 13 and the heavily doped source/drain regions 16. The silicide layers 17 preferably have a thickness of, for example, 20 nm to 70 nm. In the present embodiment, the silicide layers 17 may not be formed.

The first film 3 is formed on the n-type MIS transistor 10 and the lead 33 on the silicon substrate 1. That is, the first film 3 is formed on the gate electrode 13, the side walls 14, the silicide layers 17, and the heavily doped source/drain regions 16. The first film 3 has a thickness of, for example, about 70 nm to about 90 nm. The first film 3 is formed so as to apply a tensile stress to a channel of the n-type MIS transistor 10. The first film 3 is preferably composed of silicon nitride.

The second film 4 is formed on the first film 3. That is, the second film 4 covers the n-type MIS transistor 10 and the lead 33 on the silicon substrate 1. The second film 4 is preferably composed of silicon oxide. The second film 4 has a thickness of 10 nm to 35 nm.

The structure of the p-type MIS transistor 20 will be described below.

The n-type well region 21 is formed by ion implantation with a dopant for imparting p-type conductivity to the silicon substrate 1.

The gate insulating film 22 is formed in the n-type well region 21 of the silicon substrate 1.

The gate electrode 23 is formed on the silicon substrate 1 with the gate insulating film 22 provided therebetween. The gate electrode 23 has a thickness of, for example, about 100 nm. The gate electrode 23 has a width of, for example, about 25 nm to about 90 nm. The gate electrode 23 is preferably composed of polysilicon.

The side walls 24 are formed on side walls of the gate electrode 23. The side walls 24 are preferably composed of silicon oxide, which is an insulating material.

The source/drain extension regions 25 are formed by ion implantation with a dopant for imparting n-type conductivity. The source/drain extension regions 25 are adjacent to long sides of the rectangular pattern of the gate electrode 23, each have a width of, for example, 5 nm to 10 nm, and each have a maximum depth of, for example, 20 nm to 40 nm from the surface of the silicon substrate 1.

The heavily doped source/drain regions 26 are adjacent to ends of the side walls 24 and have a predetermined width. As shown in FIG. 1A, the heavily doped source/drain regions 26 are formed in the active region 70 except the gate electrode 23. The heavily doped source/drain regions 26 preferably have a maximum depth of, for example, 90 nm from the surface of the silicon substrate 1.

The silicide layers 27 are formed on surfaces of the gate electrode 23 and the heavily doped source/drain regions 26. The silicide layers 27 preferably have a thickness of, for example, 20 nm to 70 nm. In the present embodiment, the silicide layers 27 may not be formed.

The third film 6a is formed on the p-type MIS transistor 20, the lead 33, and the second film 4. That is, the third film 6a is formed on the gate electrode 23, the side walls 24, the silicide layers 27, and the heavily doped source/drain regions 26. The third film 6a has a thickness of, for example, about 70 nm to about 90 nm. The third film 6a is formed so as to apply a tensile stress to a channel of the p-type MIS transistor 20. The third film 6a is preferably composed of silicon nitride. The third film 6a is composed of a material having a lower etch resistance than that of a material constituting the second film 4.

The third film 6a has the region 6a′ having an end of the third film formed on the second film 4 provided on the lead 33 and having a shape such that the thickness of the end of the third film differs from the thickness of another region of the third film provided on the lead 33. The region 6a′ having the shape such that the thickness of the end of the third film differs from the thickness of another region of the third film is formed by isotropic etching described below so as to have a tapered shape. Thus, the region 6a′ having the shape such that the thickness of the end of the third film differs from the thickness of another region of the third film has a thickness smaller than that of the third film 6a. The end of the third film 6a may not be formed on the lead 33.

The gate insulating film 32 is formed on the element isolation regions 2.

The lead 33 is formed on the element isolation regions 2 with the gate insulating film 22 provided therebetween. The lead 33 has a thickness of, for example, about 100 nm. The lead 33 has a width of, for example, about 100 nm to about 150 nm. The lead 33 may be composed of polysilicon. The lead 33 is formed between the n-type MIS transistor 10 and the p-type MIS transistor 20. The lead 33 is formed below the first film 3 or the third film 6a.

The side walls 34 are formed on side walls of the lead 33. The side walls 34 may be composed of silicon oxide, which is an insulating material.

The interlayer insulating film 8 is composed of tetraethoxysilane (TEOS, Si(OC₂H₅OH)₄), formed on the entire surface of the silicon substrate 1, and has a thickness of 250 nm to 700 nm.

For example, the contact plugs 50a and 50b are each constituted by sequentially stacking a contact layer composed of, for example, titanium, a diffusion barrier layer composed of, for example, titanium nitride, and a plug material such as tungsten. The contact layers are formed so as to improve the adhesion of the diffusion barrier layers to the silicide layers 17, the silicide layers 27, and the silicide layer 37. The diffusion barrier layers are formed so as to prevent the plug material from diffusing into the interlayer insulating film.

The contact plugs 50a are electrically connected to the source/drain regions 16 serving as contact electrodes of the n-type MIS transistor 10 and to the source/drain regions 26 serving as contact electrodes of the p-type MIS transistor 20 through the silicide layers 17 and 27.

The contact plug 50b is electrically connected to the lead 33 serving as a contact electrode through the silicide layer 37 provided on the lead 33. The contact plug 50b is formed between the n-type MIS transistor 10 and the p-type MIS transistor 20.

The contact plugs 50a provided on the source/drain regions 16 pass through the interlayer insulating film 8, the first film 3, and the second film 4. The contact plugs 50a provided on the source/drain regions 26 pass through the interlayer insulating film 8 and the third film 6a. The contact plug 50b provided above the lead 33 passes through the interlayer insulating film 8, the first film 3, and the second film 4 in the region 6a′ having the shape such that the thickness of the end of the third film differs from the thickness of another region of the third film.

As will be described in a manufacturing process of the semiconductor device 100, a step of anisotropically etching the interlayer insulating film 8 to form contact holes 40 is provided before a step of forming the contact plugs 50a and 50b. The interlayer insulating film 8 is composed of silicon oxide. The third film 6a is composed of silicon nitride. That is, the material constituting the interlayer insulating film 8 is different from that constituting the third film 6a. Thus, it is difficult to etch the third film 6a composed of silicon nitride with an etching gas used for the interlayer insulating film 8 during a step of etching the interlayer insulating film 8. However, according to this embodiment, the region 6a′ having the shape such that the thickness of the end of the third film differs from the thickness of another region of the third film is formed so as to have a tapered shape by isotropic etching described below. Thus, the region 6a′ having the shape such that the thickness of the end of the third film differs from the thickness of another region of the third film has a thickness smaller than that of the third film 6a. Hence, the region 6a′ having the shape such that the thickness of the end of the third film differs from the thickness of another region of the third film can be removed in the step of etching the interlayer insulating film 8. Therefore, the region 6a′ having the shape such that the thickness of the end of the third film differs from the thickness of another region of the third film can be easily etched without an etching gas used for silicon nitride. This eliminates the need to change the etching gas according to positions of the contact holes 40, results in the formation of the contact plugs 50a and 50b in one step, and prevents the occurrence of the continuity failure of the contact plugs 50a and 50b.

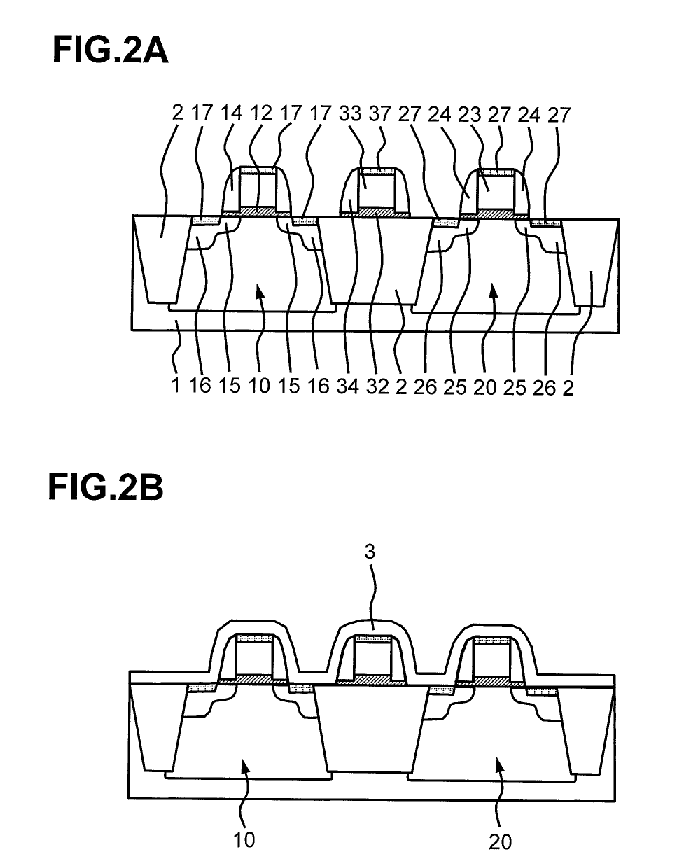

FIGS. 2A to 8 illustrate a manufacturing process of the semiconductor device 100 including the n-type MIS transistor 10 and the p-type MIS transistor 20 according to the present embodiment.

FIG. 2A illustrates steps of forming the n-type MIS transistor 10, the p-type MIS transistor 20, and the lead 33. FIG. 2A illustrates the silicon substrate 1, the element isolation regions 2, the n-type MIS transistor 10, the p-type well region 11, the gate insulating film 12, the gate electrode 13, the side walls 14, the source/drain extension regions 15, the heavily doped source/drain regions 16, the silicide layers 17, the p-type MIS transistor 20, the n-type well region 21, the gate insulating film 22, the side walls 24, the source/drain extension regions 25, the heavily doped source/drain regions 26, the silicide layers 27, the gate insulating film 32, the lead 33, the side walls 34, and the silicide layer 37. In FIG. 2A, the same elements as described in FIG. 1B are designated using the same reference numerals.

As shown in FIG. 2A, a complementary MIS structure including the n-type MIS transistor 10 and the p-type MIS transistor 20 is formed by a known process. For example, the element isolation regions 2 configured to isolate the n-type MIS transistor 10 from the p-type MIS transistor 20 are formed in the p-type silicon substrate 1.

The n-type MIS transistor 10 is formed by the following procedure. A p-type dopant such as boron is implanted in a portion of the silicon substrate 1 where the n-type MIS transistor 10 will be formed, thereby forming the p-type well region 11. The gate electrode 13 composed of polysilicon is formed on the silicon substrate 1 with the gate insulating film 12 composed of, for example, silicon oxynitride provided therebetween. An n-type dopant, e.g., phosphorus or arsenic, is implanted in portions of the silicon substrate 1 located on both sides of the gate electrode 13, thereby forming the source/drain extension regions 15. The side walls 14 composed of, for example, silicon oxide are formed on side walls of the gate insulating film 12 and the gate electrode 13. An n-type dopant, e.g., phosphorus or arsenic, is implanted in the heavily doped source/drain regions 16, thereby forming the heavily doped source/drain regions 16. In some cases, the p-type well region 11 is not formed in the silicon substrate 1 of the n-type MIS transistor 10.

The p-type MIS transistor 20 is formed by the following procedure. An n-type dopant, e.g., phosphorus, is implanted in a portion of the silicon substrate 1 where the p-type MIS transistor 20 will be formed, thereby forming the n-type well region 21. The gate electrode 23 composed of polysilicon is formed on the silicon substrate 1 with the gate insulating film 22 composed of, for example, silicon oxynitride provided therebetween. A p-type dopant, e.g., boron, is implanted in portions of the silicon substrate 1 located on both sides of the gate electrode 23, thereby forming the source/drain extension regions 25. The side walls 24 composed of, for example, silicon oxide are formed on side walls of the gate insulating film 22 and the gate electrode 23. A p-type dopant, e.g., boron, is implanted in the heavily doped source/drain regions 26, thereby forming the heavily doped source/drain regions 26.

The lead 33 is formed on the element isolation regions 2 with the gate insulating film 32 composed of, for example, silicon oxynitride provided therebetween. The lead 33 is preferably composed of polysilicon. The side walls 34 are formed on side walls of the lead 33. The side walls 34 may be composed of silicon oxide, which is an insulating material.

The silicide layers 17 are formed on the gate electrode 13 and the heavily doped source/drain regions 16. The silicide layers 27 are formed on the gate electrode 23 and the heavily doped source/drain regions 26. The silicide layer 37 is formed on the lead 33. The silicide layers 17, 27, and 37 are composed of, for example, cobalt silicide.

In the step of forming the silicide layers 17, 27, and 37, after cobalt films are formed on the gate electrode 13, the heavily doped source/drain regions 16, the gate electrode 23, the heavily doped source/drain regions 26, and the lead 33, protective films, such as titanium films or titanium nitride films, may be formed. In this case, each of the silicide layers 17, 27, and 37 preferably has a thickness of 5 nm to 30 nm. In the present embodiment, the silicide layers 17, 27, and 37 may not be formed.

The thicknesses and dopant concentrations in the foregoing CMIS structure are appropriately determined according to characteristics required for the CMIS structure.

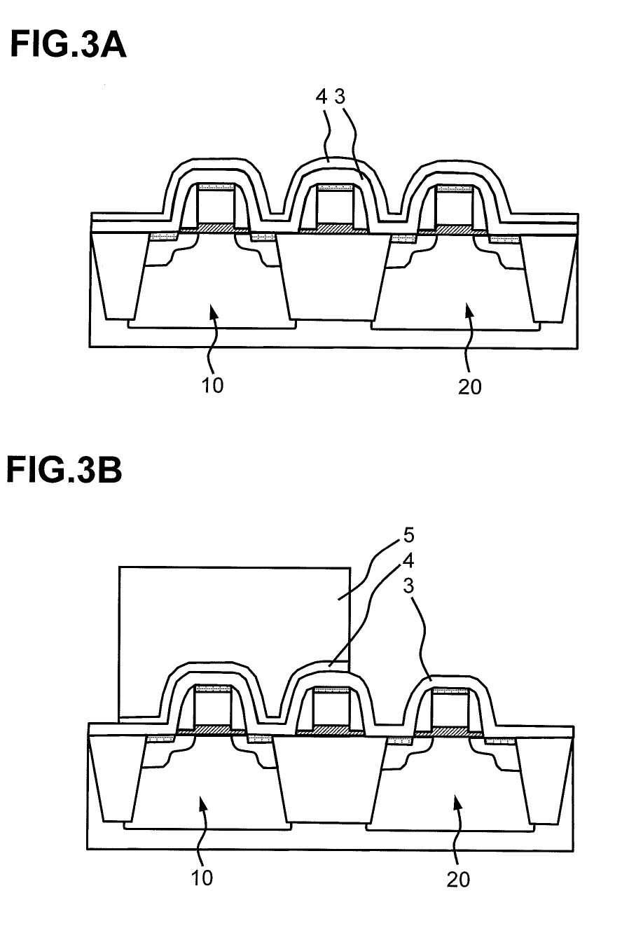

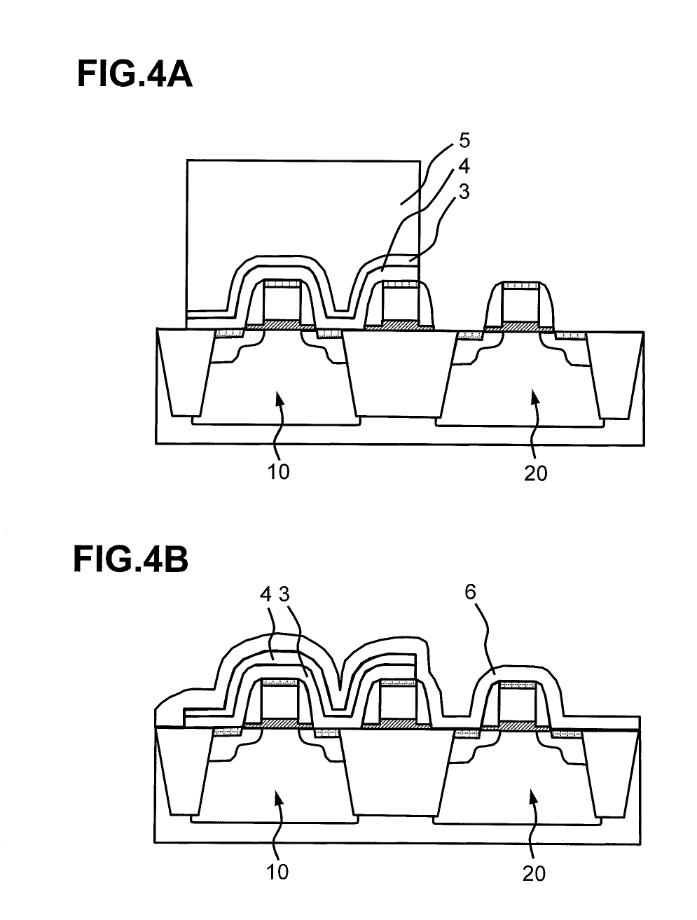

FIG. 2B illustrates a step of forming the first film 3. FIG. 4 illustrates the first film 3 in addition to the structure shown in FIG. 3.

As shown in FIG. 2B, the first film 3 composed of silicon nitride and having a thickness of 50 nm to 90 nm is formed on the entire surface of the silicon substrate 1. The first film 3 serves as a tensile stress film. For example, the first film 3 is formed by chemical vapor deposition (CVD) with a silane-based gas (e.g., SiH₂Cl₂, SiH₄, Si₂H₄, or Si₂H₆) and ammonia gas. During the deposition, the flow rate of the silane-based gas is set in the range of 5 sccm to 50 sccm, and the flow rate of ammonia gas is set in the range of 500 sccm to 10,000 sccm. Furthermore, nitrogen gas or argon gas is used as a carrier gas. The flow rate of the carrier gas is set in the range of 500 sccm to 10,000 sccm. A chamber into which the gases are introduced is controlled so as to have an internal pressure of 0.1 Torr to 400 Torr and a temperature of 400° C. to 450° C. The unit “sccm” is equivalent to a flow rate (mL/min) at 0° C. and 101.3 kPa. One Torr is equivalent to about 133.322 Pa. The first film 3 formed under the foregoing conditions has a tensile stress of about 400 MPa to about 500 MPa. Moreover, the first film 3 may be subjected to ultraviolet (UV) irradiation described below to shrink, thus increasing the tensile stress.

FIG. 3A illustrates a step of forming the second film 4. FIG. 3A illustrates the second film 4 in addition to the structure shown in FIG. 2B.

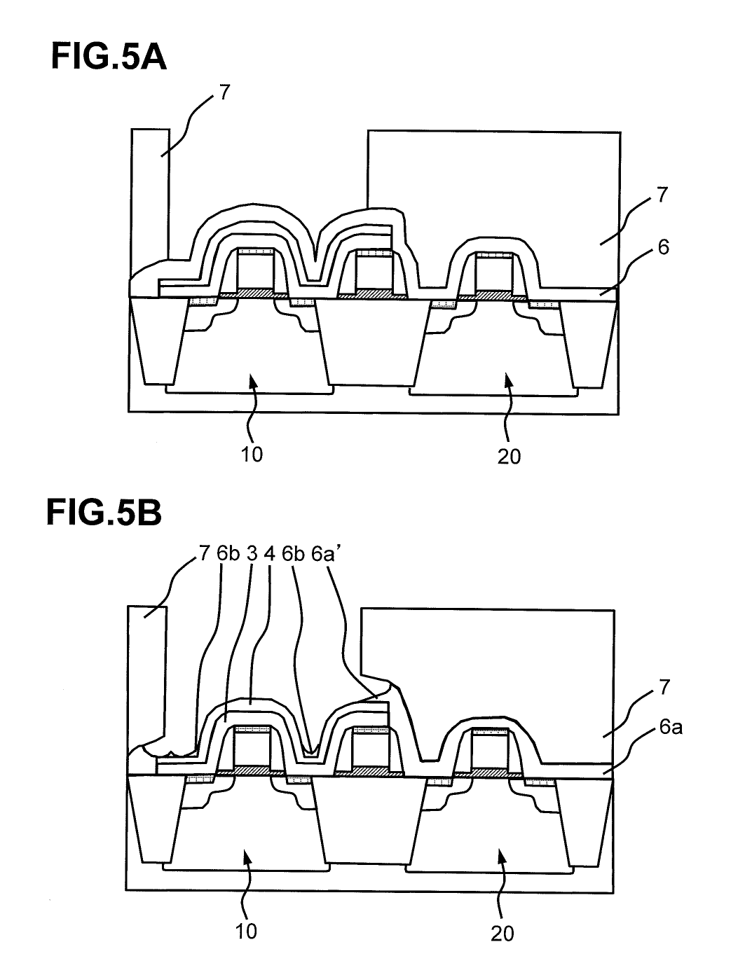

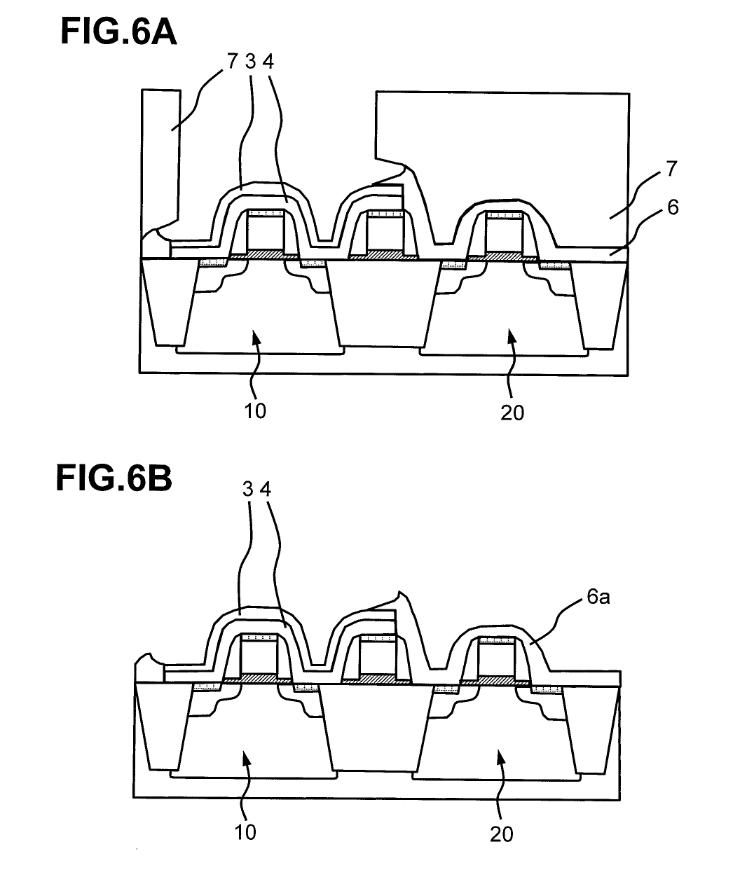

As shown in FIG. 3A, the second film 4 composed of silicon oxide is formed on the first film 3. The second film 4 is formed by, for example, plasma-enhanced CVD. The second film 4 has a thickness of 15 nm to 35 nm. In the formation of the second film 4, for example, a mixed gas of silane SiH₄ and oxygen is used. The substrate temperature is set at 350° C. to 450° C. during the plasma-enhanced CVD. The second film 4 formed here functions as an etch stop preventing the etching of the first film 3 during the etching of the third film 6a described below (see FIGS. 5B and 6A).

FIG. 3B illustrates a step of etching the second film 4. FIG. 3B illustrates a resist mask 5 in addition to the structure shown in FIG. 3A.

As shown in FIG. 3B, the resist mask 5 is formed on the side of the n-type MIS transistor 10. The second film 4 formed on the side of the p-type MIS transistor 20 is removed by etching. The etching of the second film 4 is performed by, for example, reactive ion etching with a C₄F₈/Ar/O₂ gas containing C₄F₈, which is a fluorocarbon gas. The chamber temperature is set in the range of, for example, −15° C. to +10° C. The flow rate of C₄F₈ is set in the range of 0.1 sccm to 10 sccm. The flow rate of Ar is set in the range of 100 sccm to 1,000 sccm. The flow rate of O₂ is set in the range of 0.1 sccm to 10 sccm.

FIG. 4A illustrates a step of etching the first film 3.

As shown in FIG. 4A, after the second film 4 is subjected to etching, the first film 3 formed on the side of the p-type MIS transistor 20 is removed by etching with the same resist mask 5. The etching of the first film 3 is performed by, for example, RIE with a CHF₃/Ar/O₂ gas containing CHF₃, which is a fluorocarbon gas. The chamber temperature is set in the range of, for example, 0° C. to 35° C. The flow rate of CHF₃ is set in the range of 1 sccm to 100 sccm. The flow rate of Ar is set in the range of 10 sccm to 500 sccm. The flow rate of O₂ is set in the range of 1 sccm to 100 sccm. After the first film 3 formed on the side of the p-type MIS transistor 20 is subjected to etching, the resist mask 5 is removed.

The etching of the second film 4 shown in FIG. 3B and the etching of the first film 3 shown in FIG. 4A are performed, so that the first film 3 and the second film 4 remain only on the n-type MIS transistor 10. The first film 3 applies a tensile stress to a channel of the n-type MIS transistor 10.

After the removal of the resist mask 5, the first film 3 remaining on the n-type MIS transistor 10 may be subjected to UV irradiation. The UV irradiation is performed in a UV irradiation device that can irradiate a workpiece with ultraviolet rays while the inside of a chamber is controlled so as to achieve a predetermined environment. For example, the UV irradiation is performed at an irradiation temperature of about 450° C. for about 20 minutes.

Ultraviolet rays pass through the second film 4 and reach the first film 3. The first film 3 that has been irradiated with ultraviolet rays has a tensile stress larger than that before UV irradiation and is simultaneously cured. This is because the irradiation with ultraviolet rays results in the removal of hydrogen left in the first film 3.

The tensile stress is in the range of about 400 MPa to about 500 MPa before UV irradiation. The irradiation with ultraviolet rays increases the tensile stress to about 1.8 GPa to about 2 GPa. In the present embodiment, the UV irradiation step may not be performed.

FIG. 4B illustrates a step of forming a silicon nitride film 6. FIG. 4B illustrates the silicon nitride film 6 in addition to the structure shown in FIG. 4A.

As shown in FIG. 4B, the silicon nitride film 6 for applying a compressive stress to the p-type MIS transistor 20 is formed on the entire surface of the silicon substrate 1 having the first film 3 and the second film 4. The silicon nitride film 6 has a thickness of, for example, 50 nm to 90 nm.

The silicon nitride film 6 is formed by, for example, plasma-enhanced CVD with SiH₄ gas containing a carbonaceous compound and NH₃ gas.

In the step of forming the silicon nitride film 6, the flow rate of the SiH₄ gas is set in the range of 100 sccm to 1,000 sccm, and the flow rate of NH₃ gas is set in the range of 500 sccm to 10,000 sccm. Furthermore, N₂ gas or Ar gas is used as a carrier gas. The flow rate of the carrier gas is set in the range of 500 sccm to 10,000 sccm. A chamber into which the gases are introduced is controlled so as to have an internal pressure of 0.1 Torr to 400 Torr and a temperature of 400° C. to 450° C. The RF power is set in the range of about 100 W to about 1,000 W. The formed silicon nitride film 6 usually contains carbon. The silicon nitride film 6 deposited under the foregoing conditions has a compressive stress of about 2.5 GPa to about 3 GPa.

FIG. 5A illustrates a step of forming a resist mask 7. As shown in FIG. 5A, after the silicon nitride film 6 is deposited on the entire surface, the resist mask 7 is formed on the side of the p-type MIS transistor 20.

FIG. 5B illustrates a step of removing the silicon nitride film 6 on the lead 33. FIG. 5B illustrates residues 6b of the first film 3, the third film 6a, and the region 6a′ having the shape such that the thickness of the end of the third film differs from the thickness of another region of the third film in addition to the structure shown in FIG. 5A. As shown in FIG. 5B, the silicon nitride film 6 formed on the side of the n-type MIS transistor 10 is removed by etching using the second film 4 as an etch stop. The third film 6a is composed of silicon nitride having a lower etch resistance than that of the material constituting the second film 4. Isotropic etching of the silicon nitride film 6 is performed with, for example, a CF₄/O₂ gas containing CF₄, which is a fluorocarbon gas. The chamber temperature is set in the range of, for example, 0° C. to 35° C. The pressure during the isotropic etching is set in the range of 10 Pa to 100 Pa. The flow rate of CF₄ is set in the range of 10 sccm to 100 sccm. The flow rate of O₂ is set in the range of 100 sccm to 500 sccm. The RF power is set in the range of 100 to 500 W. The isotropic etching is performed for 5 seconds to 25 seconds. In the isotropic etching step, the third film 6a formed between the n-type MIS transistor 10 and the p-type MIS transistor 20 on which the resist mask 7 is formed is removed. The processing time of the isotropic etching can be calculated from the thickness and the etch rate of the silicon nitride film 6. Alternatively, the processing time of the isotropic etching may be determined by detecting the end point in the isotropic etching of the silicon nitride film 6. The region 6a′ having the end of the third film formed on the second film 4 provided on the lead 33 and having the shape such that the thickness of the end of the third film differs from that of another region of the third film formed on the lead 33 is formed in this step. The region 6a′ having the shape such that the thickness of the end of the third film differs from the thickness of another region of the third film is formed by isotropic etching described below so as to have a tapered shape. Thus, the region 6a′ has a thickness smaller than that of the third film 6a.

Alternatively, the silicon nitride film 6 may be etched by anisotropic etching instead of isotropic etching. The conditions of the anisotropic etching are as follows: The RF power is set in the range of 400 W to 600 W, and the pressure in the anisotropic etching is set in the range of 5 mTorr to 50 mTorr.

After the completion of the isotropic etching, the residues 6b of the third film remain on the surface of the second film 4 except the second film 4 formed on the lead 33. The residues 6b of the third film represent portions of the silicon nitride film 6 unremoved by the isotropic etching on the surface of the second film 4.

FIG. 6A illustrates a step of removing the residues 6b of the third film. The residues 6b of the third film are removed by anisotropic etching.

The etching of the residues 6b of the third film is performed by, for example, RIE with a CHF₃/Ar/O₂ gas containing CHF₃, which is a fluorocarbon gas. The chamber temperature is set in the range of, for example, 0° C. to 60° C. The flow rate of CHF₃ is set in the range of 5 sccm to 100 sccm. The flow rate of Ar is set in the range of 10 sccm to 500 sccm. The flow rate of O₂ is set in the range of 1 sccm to 100 sccm. The pressure in the anisotropic etching is set in the range of 10 mTorr to 100 mTorr. The RF power in the anisotropic etching is set in the range of 100 W to 500 W. The anisotropic etching is performed for 20 seconds to 60 seconds.

By performing this step, the same members to be etched are present at portions where the contact holes 40 will be formed when a step of forming the contact holes 40 in regions where the residues 6b of the third film have been removed is performed. Thus, the formation of faulty openings of the contact holes 40 is prevented. The residues 6b of the third film may be removed by isotropic etching.

The etching of the silicon nitride film 6 shown in FIG. 5B and the etching of the residues 6b of the third film shown in FIG. 6A are performed, so that the third film 6a remains on the p-type MIS transistor 20. The third film 6a applies a tensile stress to a channel of the p-type MIS transistor 20.

FIG. 6B illustrates a step of removing the resist mask 7.

As shown in FIG. 6B, after the first film 3 formed on the side of the p-type MIS transistor 20 is etched, the resist mask 7 is removed.

By performing these steps described above, the CMIS structure including the first film 3 formed on the n-type MIS transistor 10 and the third film 6a formed on the p-type MIS transistor 20 is completed.

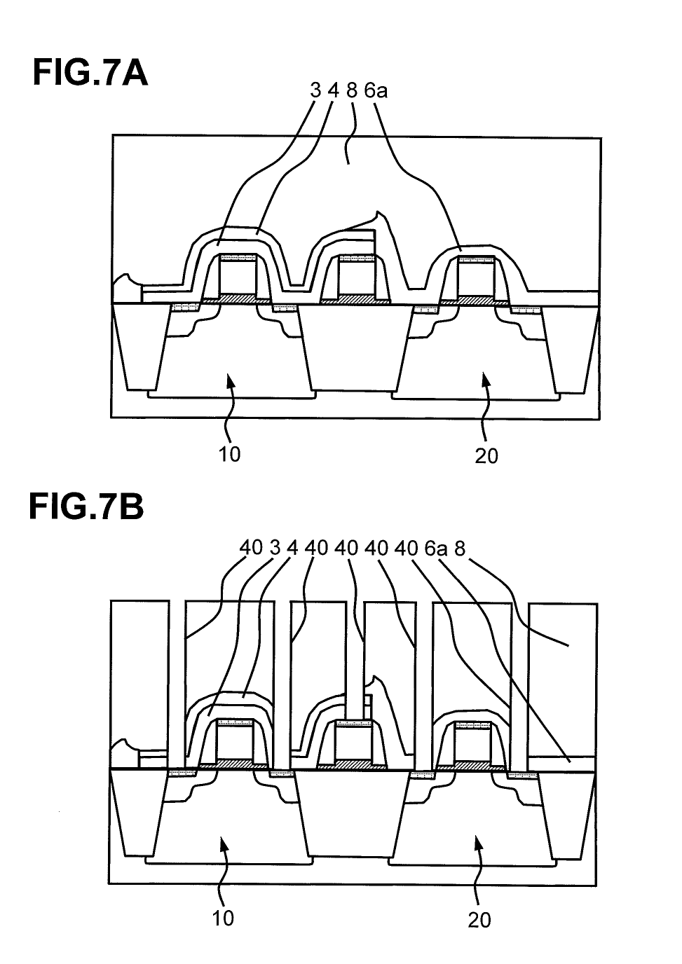

FIG. 7A illustrates a step of forming the interlayer insulating film 8. FIG. 7A illustrates the interlayer insulating film 8 in addition to the structure shown in FIG. 6B.

As shown in FIG. 7A, after the removal of the resist mask 7, for example, a TEOS film serving as the interlayer insulating film 8 is formed on the entire surface, i.e., on the second film 4 and the third film 6a. The interlayer insulating film 8 is formed by plasma-enhanced CVD with tetraethoxysilane (TEOS, Si(OC₂H₅)₄). The interlayer insulating film 8 having a thickness of 450 nm to 700 nm is formed on the entire surface and then planarized by chemical mechanical polishing (CMP) in such a manner that the ultimate thickness is about 350 nm.

FIG. 7B illustrates a step of forming the contact holes 40. FIG. 7B illustrates the contact holes 40 in addition to the structure shown in FIG. 7A.

As shown in FIG. 7B, after the formation of the interlayer insulating film 8, a resist mask (not shown) is formed. The interlayer insulating film 8, and the first film 3, the second film 4 and the third film 6a are subjected to anisotropic etching. The contact holes 40 are formed in such a manner that the silicide layers 17 formed on the surface of the heavily doped source/drain regions 16, the silicide layers 27 formed on the surface of the heavily doped source/drain regions 26, and the silicide layer 37 formed on the surface of the lead 33 located below the region 6a′ having the shape such that the thickness of the end of the third film differ-s from the thickness of another region of the third film are exposed. The etching of the interlayer insulating film 8 and the second film 4 are performed by RIE with a C₄F₈/Ar/O₂ gas containing C₄F₈, which is a fluorocarbon gas. The chamber temperature is set in the range of, for example, −15° C. to +10° C. The flow rate of C₄F₈ is set in the range of 0.1 sccm to 10 sccm. The flow rate of Ar is set in the range of 100 sccm to 1,000 sccm. The flow rate of O₂ is set in the range of 0.1 sccm to 10 sccm.

The region 6a′ having the shape such that the thickness of the end of the third film differs from the thickness of another region of the third film is formed by isotropic etching described above so as to have a tapered shape. Thus, the region 6a′ has a thickness smaller than that of the third film 6a. Therefore, in a step of etching the interlayer insulating film 8, the region 6a′ having the shape such that the thickness of the end of the third film differs from the thickness of another region of the third film is easily etched without change of the etching gas into an etching gas for the region 6a′ having the shape such that the thickness of the end of the third film differs from the thickness of another region of the third film.

The etching of the first film 3 and the third film 6a are performed by RIE with a CHF₃/Ar/O₂ gas containing CHF₃, which is a fluorocarbon gas. The chamber temperature is set in the range of, for example, 0° C. to 35° C. The flow rate of CHF₃ is set in the range of 1 sccm to 100 sccm. The flow rate of argon gas is set in the range of 10 sccm to 500 sccm. The flow rate of oxygen gas is set in the range of 1 sccm to 100 sccm.

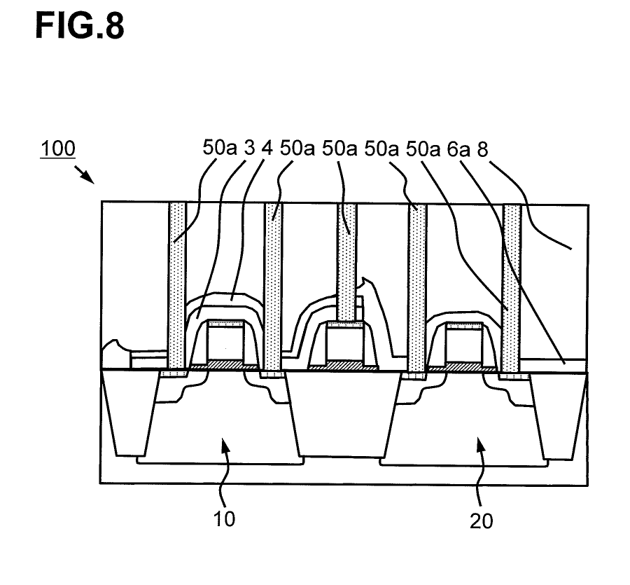

FIG. 8 illustrates a step of forming the contact plug 50b connected to the lead 33 in the region 6a′ having the shape such that the thickness of the end of the third film differs from the thickness of another region of the third film. FIG. 8 illustrates the contact plugs 50a and the contact plug 50b in addition to the structure shown in FIG. 7B. The contact plugs 50a are electrically connected to the source/drain regions 16 serving as contact electrodes of the n-type MIS transistor 10 and to the source/drain regions 26 serving as contact electrodes of the p-type MIS transistor 20 through the silicide layers 17 and the silicide layers 27. The contact plug 50b is electrically connected to the lead 33 serving as a contact electrode through the silicide layer 37. The contact plug 50b is formed between the n-type MIS transistor 10 and the p-type MIS transistor 20.

The contact plugs 50a provided on the source/drain regions 16 pass through the interlayer insulating film 8, the first film 3, and the second film 4. The contact plugs 50a provided on the source/drain regions 26 pass through the interlayer insulating film 8 and the third film 6a. The contact plug 50b provided above the lead 33 passes through the interlayer insulating film 8, the first film 3, and the second film 4 in the region 6a′ having the shape such that the thickness of the end of the third film differs from the thickness of another region of the third film.

For example, the contact plugs 50a and 50b are each constituted by sequentially stacking a contact layer composed of, for example, titanium, a diffusion barrier layer composed of, for example, titanium nitride, and a plug material such as tungsten. The contact layers are formed so as to improve the adhesion of the diffusion barrier layers to the silicide layers 17, the silicide layers 27, and the silicide layer 37. The diffusion barrier layers are formed so as to prevent the plug material from diffusing into the interlayer insulating film. The contact layers and the diffusion barrier layers in the contact plugs 50a and 50b are not shown.

As shown in FIG. 8, after the formation of the contact holes 40, a titanium film to be formed into the contact layers is formed on the entire surface of the silicon substrate 1 and bottoms of the contact holes 40 so as to have a thickness of 5 nm to 30 nm. The titanium film is formed by sputtering at a target power of 1 kW to 18 kW and a substrate bias power of 0 W to 500 W. The formation temperature is set in the range of 50° C. to 250° C. The titanium film serving as the contact layers may not be formed.

A titanium nitride film serving as the diffusion barrier layers is formed on the entire surface of the silicon substrate 1 and the contact layers so as to have a thickness of 1 nm to 10 nm. The titanium nitride film is formed by metal-organic chemical vapor deposition (MO-CVD) with tetrakis(dimethylamino)titanium (TDMAT) as a source gas. The diffusion barrier layers are formed at 300° C. to 450° C.

The plug material, which is tungsten, is deposited on the entire surface of the silicon substrate 1 and the diffusion barrier layers. The tungsten film is formed by CVD with WF₆ gas at 300° C. to 500° C. Then the titanium film, the titanium nitride film, and the tungsten film formed on the interlayer insulating film 8 are removed by CMP, thereby resulting in the completion of the contact plugs 50a and the contact plug 50b. Therefore, a semiconductor device including, on the silicon substrate 1, the n-type MIS transistor 10 having improved operational speed owing to the application of a tensile stress and the p-type MIS transistor 20 having improved operational speed owing to the application of a compressive stress is provided.

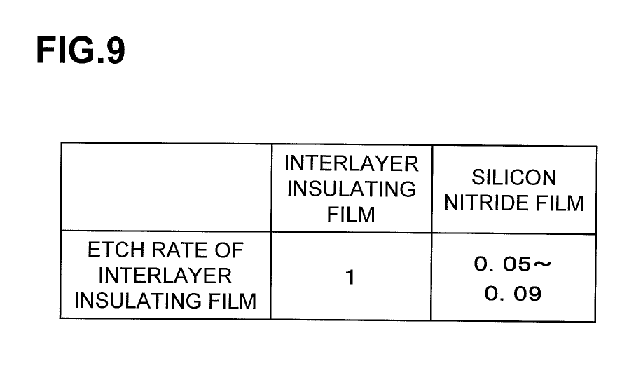

FIG. 9 is a table showing etch rates of the interlayer insulating film 8 and silicon nitride constituting the third film 6a in the step of etching the interlayer insulating film 8.

The etch rate of the interlayer insulating film 8 in the step of etching the interlayer insulating film 8 is defined as 1. In this case, the step of etching the interlayer insulating film 8 is performed by reactive ion etching (RIE) with a C₄F₈/Ar/O₂ gas containing C₄F₈, which is a fluorocarbon gas. The chamber temperature is set in the range of, for example, −15° C. to +10° C. The flow rate of C₄F₈ is set in the range of 0.1 sccm to 10 sccm. The flow rate of Ar is set in the range of 100 sccm to 1,000 sccm. The flow rate of O₂ is set in the range of 0.1 sccm to 10 sccm.

As shown in Table 1, the ratio of the etch rate of the interlayer insulating film 8 to the etch rate of silicon nitride constituting the third film 6a in the step of etching the interlayer insulating film 8 is 1:0.05 to 1:0.09.

Table 1 shows that the etch rate of the silicon nitride film 6 is lower than that of the interlayer insulating film 8. However, region 6a′ having the shape such that the thickness of the end of the third film differs from the thickness of another region of the third film is formed by isotropic etching so as to have a tapered shape. Thus, the region 6a′ has a thickness smaller than that of the third film 6a. Therefore, the region 6a′ having the shape such that the thickness of the end of the third film differs from the thickness of another region of the third film is removed in the step of etching the interlayer insulating film 8. Consequently, the region 6a′ having the shape such that the thickness of the end of the third film differs from the thickness of another region of the third film is easily etched without an etching gas for silicon nitride.

In the method of manufacturing the semiconductor device and the semiconductor device according to the embodiments of the present embodiment, the contact plug 50b is formed in the region 6a′ having the end of the third film 6a formed on the second film 4 provided on the lead 33 and having the shape such that the thickness of the end of the third film 6a differs from the thickness of another region of the third film 6a formed on the lead 33, thereby preventing the occurrence of the continuity failure of the contact plug 50b.

Furthermore, the step of forming the region 6a′ having the end of the third film 6a formed on the second film 4 and having the shape such that the thickness of the end of the third film 6a differs from the thickness of another region of the third film 6a formed on the lead 33 results in the prevention of the formation of faulty openings in the step of the contact holes, thereby preventing the occurrence of the continuity failure of the contact plug 50b.

What is claimed is:

1. A method of manufacturing a semiconductor device, comprising:
forming a wiring layer over a substrate;
forming a first film over the wiring layer;
forming a second film over the first film;
selectively etching the first and second films to form an first end of the first and second films over the wiring layer;
forming a third film over the second film;
selectively etching the third film to form a second end of the third film tapered off over the first end of the first and second films;
forming an interlayer insulating film over the second and third films;
forming a contact hole by selectively etching the interlayer insulating film, the first film, the second film and the third film; and
forming a contact plug connected to the wiring layer in the contact holes.

2. The method according to claim 1, wherein the etching rate of the interlayer insulating film is greater than the etching rate of the first, second, and third films.

3. The method according to claim 1, wherein the selectively etching the third film to form the second end of the third film tapered off over the first end of the first and second films is performed by an isotropic etching.

4. The method according to claim 1, wherein the selectively etching the third film to form the second end of the third film tapered off over the first end of the first and second films is performed by an anisotropic etching after the isotropic etching.

5. The method according to claim 4, wherein the selectively etching the third film to form the second end of the third film tapered off over the first end of the first and second films is performed by an anisotropic etching.

6. The method according to claim 1, wherein the selectively etching the third film to form the second end of the third film tapered off over the first end of the first and second films is performed by an isotropic etching after the anisotropic etching.

7. The method according to claim 1, further comprising forming a field-effect transistor having a first conductivity and a field-effect transistor having a second conductivity over the substrate,
wherein the wiring layer is formed between the field-effect transistor having the first conductivity and the field-effect transistor having the second conductivity.

8. The method according to claim 1, wherein the first film is formed over the field-effect transistor having the first conductivity, and the second film is formed over the field-effect transistor having the second conductivity over the substrate.

9. A semiconductor device, comprising:
a wiring layer formed over a substrate;
a first film formed over the wiring layer;
a second film formed over the first film;
a third film formed over the second film;
an interlayer insulating film formed over the second and third films;
a contact hall formed through the interlayer insulating film, the first film, the second film and the third film; and
a contact plug formed in the contact hall, the contact hall connected to the wiring layer;
wherein the first and second films have a first end formed over the wiring layer, and the third film has a second end tapered off over the first end.

10. The semiconductor device according to claim 9, wherein the etching rate of the interlayer insulating film is greater than the etching rate of the first, second, and third films.

11. The semiconductor device according to claim 9, further comprising a field-effect transistor having a first conductivity and a field-effect transistor having a second conductivity are formed over the substrate, wherein the wiring layer is formed between the field-effect transistor having the first conductivity and the field-effect transistor having the second conductivity.

12. The semiconductor device according to claim 9, wherein the first film is formed over the field-effect transistor having the first conductivity, and the second film is formed over the field-effect transistor having the second conductivity over the substrate.

13. The semiconductor device according to claim 9, wherein the first and third films are stress films.

14. The semiconductor device according to claim 9, wherein the first and third films comprise silicon nitride and the second film comprises silicon oxide.
